(19) United States
(12) Patent Application Publication
(10) Pub. No.: US 2024/0150531 A1
(43) Pub. Date: May 9, 2024

(54) HIGH HARDNESS FILMS

(71) Applicant: SOLVAY SPECIALTY POLYMERS USA, LLC, Alpharetta, GA (US)

(72) Inventors: Nicolas Treat, Alpharetta, GA (US); Joel Pollino, Johns Creek, GA (US); Ryan Mondschein, Cumming, GA (US); David B. Thomas, Milton, GA (US)

(73) Assignee: SOLVAY SPECIALTY POLYMERS USA, LLC, Alpharetta, GA (US)

(21) Appl. No.: 18/547,230

(22) PCT Filed: Feb. 18, 2022
(86) PCT No.: PCT/EP2022/054081

§ 371 Date: Aug. 21, 2023

Related U.S. Application Data
(60) Provisional application No. 63/152,010, filed on Feb. 22, 2021.

(51) Int. Cl. C08J 5/18; H10K 59/80

(52) U.S. Cl. CPC C08J 5/18; H10K 59/87; C08J 2365/02

(57) ABSTRACT

The present invention relates to hard optically transparent films suitable as protective films for displays, in particular flexible OLED displays.

### CROSS-REFERENCE TO RELATED APPLICATIONS

This application claims priority to U.S. provisional application No. 63/152,010 filed on Feb. 22, 2021, the whole content of this application being incorporated herein by reference for all purposes.

### TECHNICAL FIELD

The present invention relates to display technical field, especially to an optical thin film suitable for the manufacture of flexible displays, such as flexible organic electroluminescent displays (OLED).

### BACKGROUND ART

Organic electroluminescent displays (OLED) have gradually become the mainstream in the display field, because of their fast response, wide color gamut, super thinness, capability of being flexible and the like.

Polymeric optical films with high thermal stability, high dimensional stability at elevated temperatures, high hardness, high optical transparency, and high tensile strength are widely required in modern electronics for use as substrates in flexible displays and as window cover for OLEDS, in particular flexible active-matrix organic light-emitting diode (AMOLED) devices. Desired optical properties include high light transmittance, low haze and low yellowness index.

However, conventional polymeric optical films, such as polyolefin and polyester films, have poor thermal and dimensional stability while standard high-temperature polymer films, such as polyimides, have a highly colored appearance and poor optical transparency in the visible light region.

Recent advances have led to the development of colorless and transparent polyimide films, such as those marketed under the trade name Kolon™ CPI, which are characterised by low yellowness, good flexibility and high hardness.

The use of polymers comprising phenylene repeating units has been disclosed in the art for the manufacture of films and sheets. For example, U.S. Pat. No. 5,886,130 discloses kinked rigid-rod copolymers comprising phenylene units and the use thereof to form fibers, films or sheets.

U.S. Pat. No. 5,976,437 discloses linear polyphenylenes in which the polymer chain has at least 95 mole % 1,4-linkages and incorporates pendant solubilizing side groups. The linear polyphenylenes can be fabricated into films, including oriented films.

However, to the knowledge of the present Applicant, oriented films made from kinked rigid-rod polyphenylene polymers or their use as films for displays have never been disclosed in the art.

### SUMMARY OF INVENTION

Surprisingly, the Applicant found that oriented films comprising at least one kinked rigid-rod polyphenylene polymer are suitable for use in flexible displays applications.

The Applicant surprisingly found that the oriented film according to the present invention is characterised by low yellowness, high light transmittance and high hardness.

Thus, in a first aspect, the present invention relates to a film, [film (OF)] comprising at least one polyphenylene polymer [polymer (PP)].

Advantageously, film (OF) is an oriented film, either mono- or biaxially oriented.

Advantageously, said polymer (PP) is the only polymer, i.e. it is used alone, without the addition of further polymers.

Advantageously, said film (OF) is prepared by a process comprising preparing a film comprising polymer (PP), orienting said film in at least one direction, and optionally submitting said film to a thermal treatment.

In addition, film (OF) according to the present invention is characterized by pencil hardness of H or higher; and/or by a yellowness index of no more than 4.0.

### DESCRIPTION OF EMBODIMENTS

### Definitions

As used herein, the term “film” is used in a generic sense to include a plastic web, regardless of whether it is film or sheet. Typically, films of and used in the present invention have a thickness of 150 μm or less.

As used herein, the term “orientation” refers to “solid state orientation”, namely to the process of stretching of a cast film carried out at a temperature higher than the Tg (glass transition temperature) of all the polymers making up the cast film and lower than the temperature at which all the polymers making up the cast film are in the molten state. The solid-state orientation may be mono-axial, transverse or, preferably, longitudinal, or, bi-axial.

The expression “oriented film” refers to a film obtained by means of an orientation process as above defined.

The phrase “orientation ratio in machine (or longitudinal) direction or in transverse direction” refers to the number of times the film has been oriented in that direction in relation to its original size. For example, if a film has been oriented to three times its original size in the longitudinal direction, the orientation ratio in longitudinal direction is 3:1.

As used herein, the phrases “longitudinal direction” or “machine direction”, refer to a direction “along the length” of the film.

As used herein, the phrase “transverse direction”, refers to a direction across the film, perpendicular to the machine or longitudinal direction.

The use of parentheses before and after symbols or numbers identifying compounds, chemical formulae or parts of formulae has the mere purpose of better distinguishing those symbols or numbers from the rest of the text and hence said parentheses can also be omitted. In the present application:

Any description, even though described in relation to a specific embodiment, is applicable to and interchangeable with other embodiments of the present invention;

Any recitation herein of numerical ranges by endpoints includes all numbers subsumed within the recited ranges as well as the endpoints of the range and equivalents.

Film (OF)

The first object of the invention is thus a film, film (OF), comprising at least one polyphenylene polymer, polymer (PP).

Film (OF) is an oriented film. In an embodiment of the invention, film (OF) is a monoaxially oriented film. In a preferred aspect of said embodiment, film (OF) is oriented in the longitudinal or machine direction (MD).

Film (OF) may alternatively be a biaxially oriented film.

Oriented film (OF) is characterised by being birefringent.

In an embodiment, film (OF) has a free shrink of at least 5% in at least one of the longitudinal and transversal direction. The expression “free shrink” is used herein to indicate the amount of shrink that an unrestrained sample of film (OF) will exhibit in one or both orthogonal directions when heated at a temperature above the Tg of polymer (PP), for instance in an oven or in an oil bath at constant temperature.

Free shrink, may be determined as detailed hereafter in the experimental section at a temperature above the Tg of polymer (PP).

Film (OF) preferably has a free shrink in the longitudinal direction of at least 5%, more preferably of at least 10%. The free shrink in the longitudinal direction typically does not exceed 100%, preferably 50%.

In an advantageous embodiment, film (OF) has substantially no free shrink in the transversal direction, that is the free shrink is of less than 1%.

Film (OF) can consist of one single layer, i.e. a monolayer film, or it can comprise more than one layer, at least one of which comprising at least one polyphenylene polymer, polymer (PP). The additional layers may comprise a polymer (PP), or they may comprise other polymers. Film (OF) is typically a monolayer film.

Film (OF) advantageously comprises at least 95 wt. % of at least one polymer (PP) with respect to the total weight of the film. Film (OF) may comprise at least 98 wt. % of at least one polymer (PP). Film (OF) may consist of one or more polymers (PP).

In some embodiments, in addition to the at least one polymer (PP), film (OF) can further include optional additives, including but not limited to, antioxidants (e.g. ultraviolet light stabilizers and heat stabilizers), processing aids, nucleating agents, lubricants, flame retardants, smoke-suppressing agents, anti-static agents, anti-blocking agents, reinforcing fillers and the like. Among suitable fillers mention may be made of oxides, such as Si, Zr, Zn, and Ti oxides e.g. silica, alumina, zirconia, alumino-silicates (including natural and synthetic clays), zirconates and the like.

When present, the total concentration of additives in film (OF) is at least 0.1 w.%, at least 0.5 wt. %, at least 1.0 wt. %, even at least 2.0 wt % relative to the total weight of polymer (PP). The total concentration of additives in film (OF) is such not to impact its optical properties, namely transmissivity and yellowness index. The total amount of additives will normally not exceed 30 wt. %, even 20 wt % relative to the total weight of polymer (PP).

Polymer (PP) comprises recurring units (Rₚₘ) represented by the following formula:

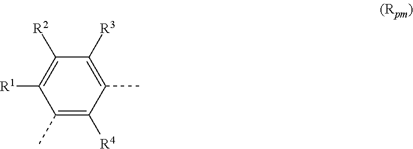

and recurring units (Rₚₚ) represented by the following formula:

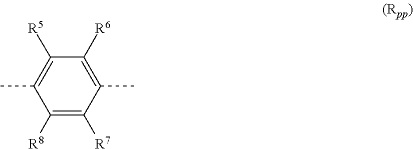

wherein

R¹, R², R³, R⁴R⁵, R⁶, R⁷, and R⁸ are each independently selected from the group consisting of hydrogen, alkyl, aryl, alkoxy, aryloxy, alkylketone, arylketone, fluoroalkyl, fluoroaryl, bromoalkyl, bromoaryl, chloroalkyl, chloroaryl, alkylsulfone, arylsulfone, alkylamide, arylamide, alkylester, arylester, fluorine, chlorine, and bromine.

Polymer (PP) comprises at least 5 mole % (per 100 moles of polymer (PP)), even at least 10 mole %, at least 12 mole % and preferably at least 15 mole %, of recurring units (Rₚₘ). Polymer (PP) may comprise 50 mole % or less (per 100 moles of polymer (PP)), even 40 mole % or less of recurring units (Rₚₘ).

Polymer (PP) comprises at least 10 mole % (per 100 moles of polymer (PP)) of recurring units (Rₚₚ). Advantageously polymer (PP) comprises at least 40 mole %, preferably at least 50 mole %, even at least 60 mole % of recurring units (Rₚₚ). Advantageously, Polymer (PP) may comprise 70 mole % or more (per 100 moles of polymer (PP)), even 85 mole % or more of recurring units (Rₚₚ).

In some embodiments, polymer (PP) may comprise 15 to 5 mole % (per 100 moles of polymer (PP)) of recurring units (Rₚₘ) and 85 to 95 mole % of recurring units (Rₚₚ).

In recurring units (Rₚₘ) and (Rₚₚ) Preferably, one or more of R¹, R², R³, and R⁴ is independently represented by formula Ar-T-,

wherein
Ar is represented by a formula selected from the following group of formulae:

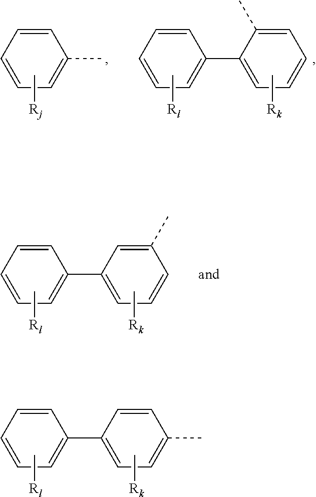

wherein
each Rⱼ, Rₖ and Rₗ is independently selected from the group consisting of hydrogen, halogen, alkyl, alkenyl, alkynyl, aryl, ether, thioether, carboxylic acid, ester, amide, imide, alkali or alkaline earth metal sulfonate, alkyl sulfonate, alkali or alkaline earth metal phosphonate, alkyl phosphonate, amine and quaternary ammonium,
with j and l, equal or different from each other, being independently 0, 1, 2, 3, 4, or 5 and,
k, equal or different from j or l, being independently 0, 1, 2, 3 or 4;
T is selected from the group consisting of —CH₂—; —O—; —SO₂₋; —S—; —C(O)—; —C(CH₃)₂—; —C(CF₃)₂—; —C(═CCl₂)—; —C(CH₃)(CH₂CH₂COOH)—; —N═N—; —R^{a}C═CR^{b}—,

wherein
each R^{a} and R^{b}, independently of one another, is hydrogen, C₁-C₁₂-alkyl, C₁-C₁₂-alkoxy, or C₆-C₁₈-aryl group; —(CH₂)ₙ— and —(CF₂)ₙ— with n being an integer from 1 to 6; a linear or branched aliphatic divalent group having from 1 to 6 carbon atoms.

In some embodiments, one or more of R¹, R², R³, and R⁴ is represented by formula:

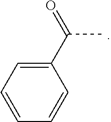

In some embodiments, the repeat unit (Rₚₘ) is represented by the formula

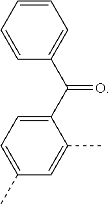

In some embodiments, one or more of R⁵, R⁶, R⁷, and R⁸ is independently represented by formula Ar″-T″-,

wherein
Ar″ is represented by a formula selected from the following group of formulae

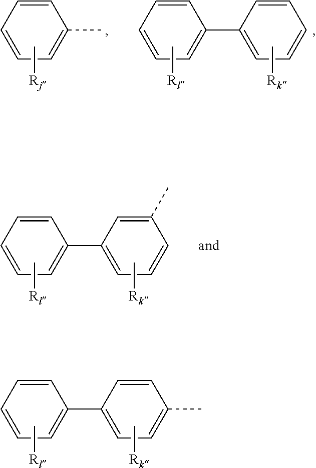

wherein
each R_{j″}, R_{k″} and R_{l″} is independently selected from the group consisting of hydrogen, halogen, alkyl, alkenyl, alkynyl, aryl, ether, thioether, carboxylic acid, ester, amide, imide, alkali or alkaline earth metal sulfonate, alkyl sulfonate, alkali or alkaline earth metal phosphonate, alkyl phosphonate, amine and quaternary ammonium,
j″ and l″, equal or different from each other being independently 0, 1, 2, 3, 4, or 5 and,
k″, equal or different from j″ or l″, being independently 0, 1, 2, 3 or 4;
T″ is selected from the group consisting of —CH₂—; —O—; —SO₂₋; —S—; —C(O)—; —C(CH₃)₂—; —C(CF₃)₂—; —C(═CCl₂)—; —C(CH₃)(CH₂CH₂COOH)—; —N═N—; —R^{a}C═CR^{b}—,
wherein each R^{a} and R^{b}, independently of one another, is hydrogen, C₁-C₁₂-alkyl, C₁-C₁₂-alkoxy, or C₆-C₁₈-aryl group; —(CH₂)ₙ— and —(CF₂)ₙ— with n being an integer from 1 to 6; a linear or branched aliphatic divalent group having from 1 to 6 carbon atoms.

In some embodiments, the repeat unit (Rₚₚ) is represented by the formula:

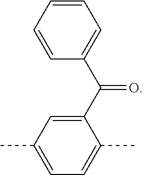

In a preferred embodiment, said polymer (PP) is commercially available from Solvay Specialty Polymers, under the tradename PrimoSpire® SRP.

Typically, film (OF) has a thickness of 150 μm or less, preferably of 120 μm or less, more preferably of 100 μm or less. Film (OF) has a thickness of 15 μm or more, preferably of 20 μm or more.

Film (OF) may advantageously have a thickness of 20 to 85 μm, preferably 25 to 75 μm.

The Applicant has surprisingly found that oriented films comprising at least one polymer (PP) have high values of hardness and tensile modulus together with excellent optical properties, such as low yellowness and high transmissivity. This combination of properties makes them highly suitable for use as protective films in display applications.

In an embodiment, film (OF) has a pencil hardness, measured according to ASTM D3363, rated H or higher, advantageously rated 2H or higher.

In still an embodiment film (OF) has a Young's modulus in at least one of the machine or transverse direction equal to or greater than 6.0 GPa, when measured according to ASTM D882.

In another embodiment, film (OF) has a yellowness index, measured according to ASTM E313, of 4.5 or less, preferably of 4.0 or less, even 3.5 or less.

In a further embodiment, film (OF) has an average optical transmissivity in the 380-750 nm range of at least 80%. Optical properties were measured on 50 μm thick films.

Film (OF) of the invention can be manufactured according to techniques known in the art.

A further object of the invention is a method for the manufacture of film (OF).

According to a first embodiment of the invention, the process for manufacturing film (OF) comprises:
(i) providing a liquid composition (C^{L}) comprising:
   at least one polymer (PP) as defined above, and
   a liquid medium;
(ii) processing composition (C^{L}) provided in step (i) to obtain a film;
(iii) orienting, in at least one of the machine (MD) and/or transverse directions (TD), the film obtained from step (ii).

In step (i), composition (C^{L}) is manufactured by any conventional technique. For instance, the liquid medium may be added to polymer (PP), or, preferably, polymer (PP) may be added to the liquid medium, or even polymer (PP) and the liquid medium may be simultaneously mixed.

Any suitable mixing equipment may be used. The mixing of polymer (PP) and the liquid medium may be conveniently carried out in a sealed container, optionally held under an inert atmosphere.

Notable, non-limiting examples of suitable liquid mediums are for instance polar aprotic solvents such as: N-methyl-pyrrolidone (NMP), dimethyl acetamide (DMAc), dimethylformamide (DMF), dimethylsulfoxide (DMSO), tetrahydrofuran (THF), methyl-5-dimethylamino-2-methyl-5-oxopentanoate (commercially available under the tradename Rhodialsov Polarclean®), triethylphosphate (TEP), and chlorinated solvents such as chloroform, dichloromethane.

In step (ii), composition (C^{L}) is typically processed by casting, thereby providing a film. Casting generally involves a step wherein a casting knife, a draw-down bar or a slot die is used to spread an even film of liquid composition (C^{L}) across a suitable support. A drying step is then typically performed to remove the liquid medium from the cast film, or tape.

The film or tape obtained in step (ii), is subjected to a solid-state orientation process in step (iii) in at least one of the machine (MD) and/or transverse directions (TD) as detailed hereafter.

In order to remove any residual stress, the film obtained from step (iii) may be optionally subjected to a heat-setting or annealing step, that is a step wherein the film is heated well below the softening temperature and allowed to cool.

Alternatively, the film according to the present invention may be obtained via extrusion followed by orientation and optionally annealing or heat-setting.

Hence, the process according to a second embodiment of the invention comprises the following steps:
(i\hat{ }) providing at least one polymer (PP) as defined above;
(ii\hat{ }) melt processing the at least one polymer (PP) into a film;
(iii\hat{ }) orienting, in at least one of the machine (MD) and/or transverse directions (TD), the film obtained from step (ii\hat{ }).

According to this technique, at least one polymer (PP) is fed to an extruder, melted and then extruded through a die so as to obtain a molten tape, which is then oriented in step (iii\hat{ }). Polymer (PP) is typically extruded through a die at temperatures generally lower than 250° C., preferably lower than 200° C. Twin screw extruders are preferred devices for processing of the at least one polymer (PP).

Solid-state orientation in steps (iii) and (iii\hat{ }) in the processes according to the first and second embodiment can be accomplished through a flat film orientation process.

A flat film orientation process for the preparation of film (OF) can be described as follows. The film comprising at least one polymer (PP) obtained at the end of steps (ii) and (ii\hat{ }) is heated to the suitably selected orientation temperature, the heated film is then stretched at a stretching ratio of at least 1.2:1 in at least one direction, and finally cooled to provide an oriented film. The oriented film may optionally be annealed or heat-set by means of a further heat treatment.

When monoaxially oriented, the stretching ratio for films of the invention is at least 1.2:1, preferably at least 1.5:1, even 2:1, typically in the longitudinal or machine direction. Advantageous results in terms of pencil hardness and modulus were obtained with stretching ratios of 1.5:1 to 2:1.

When biaxially oriented, the stretching ratio for films of the invention is at least 1.2:1, even 1.25:1 in each direction.

The preferred orientation process for the manufacture of the films according to the present invention involves a monoaxial orientation process. Monoaxial orientation may be accomplished by drawing the film or sheet, obtained either by casting from a solution or by extrusion, preferably by casting from a solution, between at least two pairs of rolls rotating at different speeds wherein one pair of rolls, downstream to at least one other pair, rotates faster than the upstream pair(s) of rolls. A first pair of rolls heats and stabilizes the sheet surface temperature and allows time for inner sheet temperature balance. The second pair of rolls, by rotating faster, stretches the film in the longitudinal direction. The nip controls simultaneous rolling and stretching at optimum orientation temperature. Typically, the set comprises at least a third set of rolls which are used for heat setting and/or cooling the monoaxially stretched polymeric sheet.

Typical orientation temperatures for the present films range from 150 degrees to 220° C., more preferably from 160 to 200° C., even from 170 to 190° C.

Alternatively, the film according to the present invention may be obtained by stretching in the solid state with a simultaneous or a sequential tenterframe process. While the simultaneous tenterframe process provides only biaxially oriented sheets, a sequential tenterframe process allows to obtain either biaxially oriented sheets and mono-axially oriented (MD or TD) sheets. The film is then rapidly cooled to somehow freeze the molecules of the film in their oriented state and wound.

The films of the invention may be used in a large range of applications where high hardness and transparency are required.

Non-limiting examples of suitable applications are as protective layers in any application requiring hardness and good optical properties, such as displays in general, for instance LCD displays. An advantageous application for the inventive fils is as cover layer in flexible displays.

A further object of the invention is hence an article comprising film (OF), in particular a display, typically a flexible OLED display, comprising film (OF).

The invention will be herein after illustrated in greater detail by means of the Examples contained in the following Experimental Section; the Examples are merely illustrative and are by no means to be interpreted as limiting the scope of the invention.

Experimental Section

Raw Materials

N-Methyl pyrrolidone (NMP) was obtained from Fisher Scientific.

Primospire® PR 120 (polyphenylene) was obtained from Solvay Specialty Polymers.

Methods

Mechanical (Tensile) Test

The tensile modulus, strength, and elongation at break were measured according to ASTM D882 in the machine direction.

Pencil Hardness

The pencil hardness was measured using ASTM D3363, with a pencil load of 750 g.

Free Shrink

A sample of film of known dimensions was dipped into an oil bath at 190-200° C. for 15 sec. The samples was removed and its dimensions re-measured. The % shrinkage was calculated as the ratio: (dᵢₙᵢₜᵢₐₗ−d_{final})/(dᵢₙᵢₜᵢₐₗ).

Yellowness Index

The yellowness index was measured according to ASTM E313 on films.

### Example 1—General Procedure for the Preparation of Solution Cast Films

20 g of polyphenylene (Primospire® PR-120) was charged into a 250 mL round bottomed flask. To this was added 113.3 g of N-methyl pyrrolidone, and stirred at 80° C. until the polymer dissolved. The solution thus obtained was coated on a glass substrate, dried on a hot plate at 80° C. for 1 hour, then placed in an oven heated to 200° C. for 16 h. The films were taken out of the oven, and removed from the glass to obtain a polyphenylene film having a thickness of 50-60 micron.

### Example 2: General Procedure for the Preparation of Oriented Films

The polyphenylene film as produced in Example 1 was placed into a Karo IV Laboratory Stretcher manufactured by Bruckner GmbH. The film was stretched uniaxially (Examples 2a-2d) or biaxially (Example 2e). The stretch ratio in the machine (MD) and transverse (TD) directions and the properties of the resulting films are summarized in Table 1.

TABLE 1

| Example | 1 | 2a | 2b | 2c | 2d | 2e |
|---|---|---|---|---|---|---|
| MD Stretch | 0 | 1.40 | 1.50 | 1.75 | 2.00 | 1.50 |
| TD Stretch | 0 | 0 | 0 | 0 | 0 | 1.15 |
| % shrink (MD) | 0 | 18 | 20 | n/a | n/a | n/a |
| Young's Modulus | 5.7 | 6.8 | 7.7 | 9.2 | 10.6 | 7.5* |
| (GPa) | | | | | | |
| Tensile Strength | 148 | 179 | 198 | 154 | 142 | 182* |
| (MPa) | | | | | | |
| Elongation at break | 3.4 | 3.7 | 3.3 | 1.9 | 1.4 | 3.0* |
| (%) | | | | | | |
| Film Thickness (μm) | 48 | 40 | 38 | 30 | 30 | 30 |
| Yellowness Index | n/a | 3.8 | 4.3 | n/a | n/a | n/a |
| Pencil Hardness | F | H | 2H | 2H | H | 2H |

*Measured in MD

The results in Table 1 show that oriented films of the invention have improved mechanical properties and hardness with respect to non oriented films comprising the same polymer (PP).

The oriented films of the invention have good optical properties, notably low yellowness.

1. An oriented film, [film (OF)], film (OF), comprising at least one polyphenylene polymer [polymer (PP)], polymer (PP), comprising recurring units (Rₚₘ) represented by the following formula: 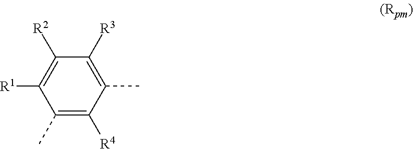
and recurring units (Rₚₚ) represented by the following formula: 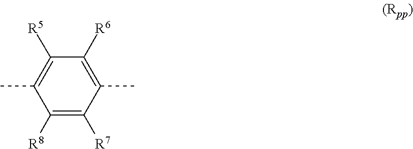
wherein
R¹, R², R³, R⁴R⁵, R⁶, R⁷, and R⁸ are each independently selected from the group consisting of hydrogen, alkyl, aryl, alkoxy, aryloxy, alkylketone, arylketone, fluoroalkyl, fluoroaryl, bromoalkyl, bromoaryl, chloroalkyl, chloroaryl, alkylsulfone, arylsulfone, alkylamide, arylamide, alkylester, arylester, fluorine, chlorine, and bromine.

2. The film according to claim 1 wherein polymer (PP) comprises at least 5 mole % and/or at most 50 mole % of recurring units (Rₚₘ).

3. The film of claim 1 wherein polymer (PP) comprises at least 50 mole % of recurring units (Rₚₚ).

4. The film according to claim 1, wherein one or more of R¹, R², R³, and R⁴ is independently represented by formula Ar-T-, wherein Ar is represented by a formula selected from the following group of formulae: 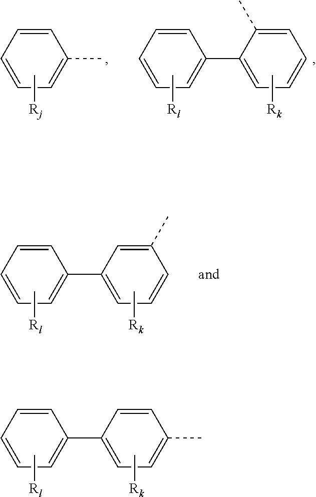
wherein
each Rⱼ, Rₖ and Rₗ is independently selected from the group consisting of hydrogen, halogen, alkyl, alkenyl, alkynyl, aryl, ether, thioether, carboxylic acid, ester, amide, imide, alkali or alkaline earth metal sulfonate, alkyl sulfonate, alkali or alkaline earth metal phosphonate, alkyl phosphonate, amine and quaternary ammonium,
with j and l, equal or different from each other, being independently 0, 1, 2, 3, 4, or 5 and,
k, equal or different from j or 1, being independently 0, 1, 2, 3 or 4;
T is selected from the group consisting of —CH₂—; —O—; —SO₂₋; —S—; —C(O)—; —C(CH₃)₂—; —C(CF₃)₂—; —C(═CCl₂)—; —C(CH₃)(CH₂CH₂COOH)—; —N═N—; —R^{a}C═CR^{b}—,
wherein each R^{a} and R b, independently of one another, is hydrogen, C₁-C₁₂-alkyl, C₁-C₁₂-alkoxy, or C₆-C₁₈-aryl group; —(CH₂)ₙ— and —(CF₂)ₙ— with n being an integer from 1 to 6; a linear or branched aliphatic divalent group having from 1 to 6 carbon atoms.

5. The film according to claim 1, wherein one or more of R¹, R², R³, and R⁴ is represented by formula:

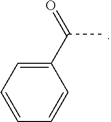

6. The film according to claim 1, wherein the recurring unit (Rₚₘ) is represented by the formula

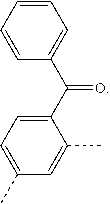

7. The film according to claim 1, wherein the recurring unit (Rₚₚ) is represented by the formula:

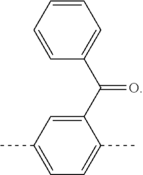

8. The film according to claim 1, which has a free shrink of at least 5% in at least one direction.

9. The film according to claim 1, which has:
a pencil hardness rating of not less than H; and/or
a Young's modulus equal to or greater than 6.0 GPa in at least one direction; and/or
a yellowness index of less than 4.5; and/or
an average optical transmissivity in the 380-750 nm range of at least 80%.

10. A process for making film (OF) of claim 1 comprising:
(i) providing a liquid composition (C^{L}) comprising: polymer (PP), and a liquid medium;
(ii) processing composition (C^{L}) provided in step (i) to obtain a film;
(iii) orienting, in at least one of the machine and/or transverse directions, the film obtained from step (ii), and
(iv) optionally heat-setting the oriented film obtained from step (iii).

11. A process for making film (OF) of claim 1 comprising:
(i\hat{ }) providing a solid composition (C^{S}) comprising at least one polymer (PP);
(ii\hat{ }) melt processing the solid composition into a film;
(iii\hat{ }) orienting, in at least one of the machine and/or transverse directions, the film obtained from step (ii\hat{ }), and
(iv\hat{ }) optionally heat-setting the oriented film obtained from step (iii\hat{ }).

12. The process according to claim 10, wherein orienting step (iii) is performed by heating the film obtained in step (ii) to its softening temperature and by stretching it in the solid state in one direction.

13. The process according to claim 12 wherein stretching is performed using at least two pairs of rolls wherein at least one pair of rolls, downstream to the at least one other pair, rotates faster than the other pair of rolls.

14. A display comprising the film (OF) of claim 1.

15. The film of claim 1 wherein polymer (PP) comprises at least 70 mole % of recurring units (Rₚₚ).

16. The process according to claim 11, wherein orienting step (iii\hat{ }) is performed by heating the film obtained in step (ii\hat{ }) to its softening temperature and by stretching it in the solid state in one direction.

17. The process according to claim 16 wherein stretching is performed using at least two pairs of rolls wherein at least one pair of rolls, downstream to the at least one other pair, rotates faster than the other pair of rolls.
